(19) United States
(12) Patent Application Publication
(10) Pub. No.: US 2025/0357106 A1
(43) Pub. Date: Nov. 20, 2025

(54) PRECURSOR COMPOUND FOR THIN FILM FORMATION AND METHOD FOR MANUFACTURING SEMICONDUCTOR DEVICE USING SAME

(71) Applicants: SK hynix Inc., Icheon-si (KR); DONGJIN SEMICHEM CO., LTD., Incheon (KR)

(72) Inventors: Su Pill CHUN, Icheon-si Gyeonggi-do (KR); Hwan KIM, Icheon-si Gyeonggi-do (KR); Dong Kyun LEE, Icheon-si Gyeonggi-do (KR); Sang Hyun LEE, Icheon-si Gyeonggi-do (KR); So Jeong YEO, Gwangju (KR); Cheolkyu BOK, Seoul (KR); Jae Woo LEE, Incheon (KR); Jun Young KIM, Jeonju-si Jeonbuk-do (KR); Ha Kyung YUN, Seoul (KR)

(21) Appl. No.: 19/288,585

(22) Filed: Aug. 1, 2025

Related U.S. Application Data
(63) Continuation of application No. PCT/KR2024/095197, filed on Feb. 15, 2024.

(30) Foreign Application Priority Data
Apr. 18, 2023 (KR) 10-2023-0050613

(51) Int. Cl. H01L 21/02; C23C 16/455

(52) U.S. Cl. CPC H01L 21/02205; C23C 16/45553; H01L 21/0228

(57) ABSTRACT

The present techniques provide a precursor compound of chemical formula 1 for thin film formation and a preparation method therefor, wherein a photoresist layer can be prevented from undergoing pattern collapse by reducing the exposure time for pattern formation and minimizing the thickness of a lower layer with an etching selectivity similar to that of a photoresist or omitting the lower layer during post-exposure etching. In chemical formula 1, R⁰ is Si, Sn, Ge, Sb, In, Hf, Zr, Ti, or Te; R¹ is CH₃, CF₃, CH═CH₂, halogen, or phenyl; R² and R²′ each are each independently alkyl or alkoxy; R³ is amine or halogen; R is hydrogen or halogen; n is an integer of 1-7.

### CROSS REFERENCE TO RELATED APPLICATION

This application is a bypass continuation of pending PCT International Application No. PCT/KR2024/095197, which was filed on Feb. 15, 2024, and which claims priority to and the benefit of Korean Patent Application No. 10-2023-0050613, which was filed in Korean Intellectual Property Office on Apr. 18, 2023, the disclosure of which are incorporated herein by reference in its entirety.

### TECHNICAL FIELD

The present disclosure relates to a precursor compound for forming a thin film and a method of manufacturing a semiconductor device and relates to a precursor compound for a lower layer that is formed under a photoresist layer and a method of manufacturing a semiconductor device using the same.

### BACKGROUND ART

A photolithography technology is a technology in which high resolution circuitry within a semiconductor device is formed by exposing a photoresist (hereinafter referred to as a “resist”) on a substrate to a light source.

In general, a lithography technology using the resist may be performed by the following method.

First, after a resist composition including a polymer matrix, a photoacid generator, a solvent, and other additives capable of improving performance are spin-coated on a silicon wafer, the resist composition is hardened to form a resist film. Next, the formed resist film is exposed to a light source in a pattern-wise manner and selectively heated, thus causing a post-exposure bake (PEB) chemical conversion. When a difference in the solubility between exposed areas of the resist film and unexposed areas of the resist film occurs due to such chemical conversion, a resist pattern image is generated on a wafer by performing a developing process using a solvent. In the exposure process, in general, radiation with wavelengths ranging from near ultraviolet (UV) to deep ultraviolet (DUV) and extreme ultraviolet (EUV) is used as light sources.

In such a lithography process, in general, a stack in which a substrate, a lower layer, and a photoresist layer are stack is used. In order to form a pattern on the stack, the pattern is formed by selectively etching the lower layer when etching is performed after exposure. However, when an actual process is applied, there are problems in that a shape of the pattern becomes poor because the photoresist layer on a surface of the stack is also etched upon etching after the exposure and thus performance of a semiconductor device is degraded.

### DISCLOSURE

### Technical Problem

An embodiment of the present disclosure provides a precursor compound for forming a thin film, which can reduce an exposure time for forming a pattern and also prevent the pattern collapse of a photoresist layer by minimizing or omitting the thickness of a lower layer having etch selectivity similar to the etch selectivity of a photoresist upon etching after exposure, and a method of manufacturing the same.

### Technical Solution

A precursor compound for forming a thin film according to an embodiment of the present disclosure may be a precursor compound for forming a thin film, comprising a material of Chemical Formula 1.

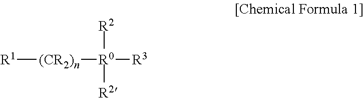

(In Chemical Formula 1, R⁰ is Si, Sn, Ge, Sb, In, Hf, Zr, Ti, or Te, R¹ is CH₃, CF₃, CH═CH₂, halogen, or phenyl, R² and R²′ are each independently an alkyl group or an alkoxy group, R³ is amine or halogen, R is hydrogen or halogen, and n is an integer of 1 to 7)

Preferably, in Chemical Formula 1, R⁰ may be Si or Sn, R¹ may be CF₃ or I, R² and R²′ may each be independently CH₃, C₂H₅, C₃H₇, OCH₃, or OC₂H₅, R³ may be N(CH₃)₂ or N[(CH₂)CH₃]₂, and R may be H. In this case, in Chemical Formula 1, n may be an integer of 1 to 4.

A method of manufacturing a semiconductor device according to an embodiment of the present disclosure may include preparing a substrate, preparing a precursor including a material of Chemical Formula 1, that is, a material for forming a lower layer, forming a lower layer by depositing the precursor including the material of Chemical Formula 1 on a substrate by atomic layer deposition (ALD) method, and forming a photoresist layer on the lower layer.

The forming of the lower layer comprising supplying the precursor including the material of Chemical Formula 1 and supplying a purge gas. A cycle in which the supplying of the precursor and the supplying of the purge gas are defined as one cycle may be repeated at least once.

### Advantageous Effects

The present technology can reduce exposure time for forming a pattern and also prevent the pattern collapse of the photoresist layer by minimizing or omitting the thickness of the lower layer having etch selectivity similar to the etch selectivity of the photoresist upon etching after exposure.

Furthermore, the lower layer can be formed as an ultra thin film of 10 Å while sufficiently securing adhesive strength between the photoresist layer and the substrate.

### BRIEF DESCRIPTION OF DRAWINGS

FIG. 1 is a diagram schematically illustrating a stack structure of a semiconductor device 100 according to the present embodiment.

FIG. 2 is a process flowchart for describing a method of manufacturing the semiconductor device according to the present embodiment.

FIG. 3 is a diagram simply illustrating a process of depositing a precursor according to an embodiment.

### MODE FOR INVENTION

Terms or words used in the specification and the claims should not be construed as having common or dictionary meanings, but should be construed as having meanings and concepts that comply with the technical spirit of the present disclosure based on the principle that the inventor may appropriately define the concepts of the terms in order to describe his or her disclosure in the best manner.

The terms used in this specification are used to only describe exemplary embodiments and are not intended to restrict the present embodiment. An expression of the singular number includes an expression of the plural number unless clearly defined otherwise in the context.

In each of the processes, symbols are used for convenience of a description, and the symbols do not describe the order of the processes. The processes may be performed in order different from order described in the context unless a specific order is clearly described in the context. That is, the processes may be performed according to the described order, may be performed substantially simultaneously, or may be performed in reverse order.

It is to be understood that in this specification, a term, such as “include”, “comprise”, or “have”, is intended to designate that a practiced characteristic, number, step, component, or a combination of them is present and does not exclude the existence or addition of one or more other characteristics, numbers, steps, components, or combinations of them in advance.

An atomic layer deposition (ALD) process may be performed by using a. source gas input, b. purge, c. reaction gas input, and d. purge as one cycle or may include a half ALD process that is performed by using two processes of a′. gas input and b′. purge as one cycle. In this specification, an “ALD process using a precursor compound of Chemical Formula 1” may be performed by the half ALD process.

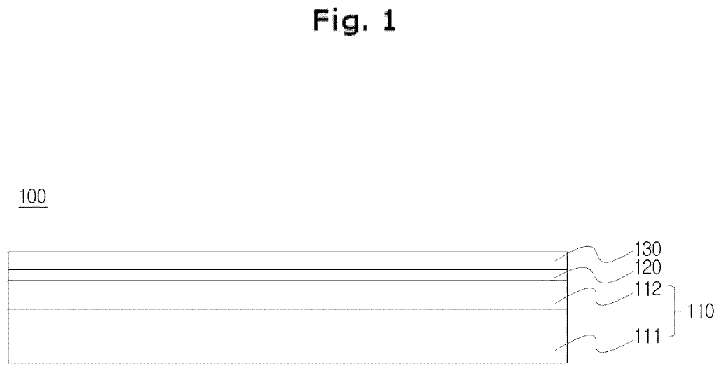

Referring to FIG. 1, the present embodiment relates to a precursor compound for forming a thin film and a method of manufacturing the same. More specifically, the precursor compound for forming a lower layer 120 may be supplied onto a substrate 110, and may. A lower layer 120 may be formed below a photoresist layer 130.

The precursor compound for forming a thin film according to the present embodiment may be expressed as Chemical Formula 1.

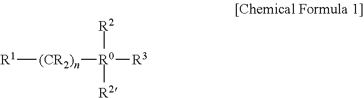

(In Chemical Formula 1, R⁰ is Si, Sn, Ge, Sb, In, Hf, Zr, Ti, or Te, R¹ is CH₃, CF₃, CH═CH₂, halogen, or phenyl, R² and R²′ are each independently an alkyl group or an alkoxy group, R³ is amine or halogen, R is hydrogen or halogen, and n is an integer of 1 to 7)

As the precursor including Chemical Formula 1, preferably, R⁰ is Si or Sn, R¹ is CF₃ or I, R² and R²′ are each independently CH₃, C₂H₅, C₃H₇, OCH₃, or OC₂H₅, R³ is N(CH₃)₂ or N[(CH₂)CH₃]₂, and a compound having an integer of 1 to 4 be used as n.

Precursors exemplarily expressed as Chemical Formula 2 to 9, among precursors of Chemical Formula 1, may be applied.

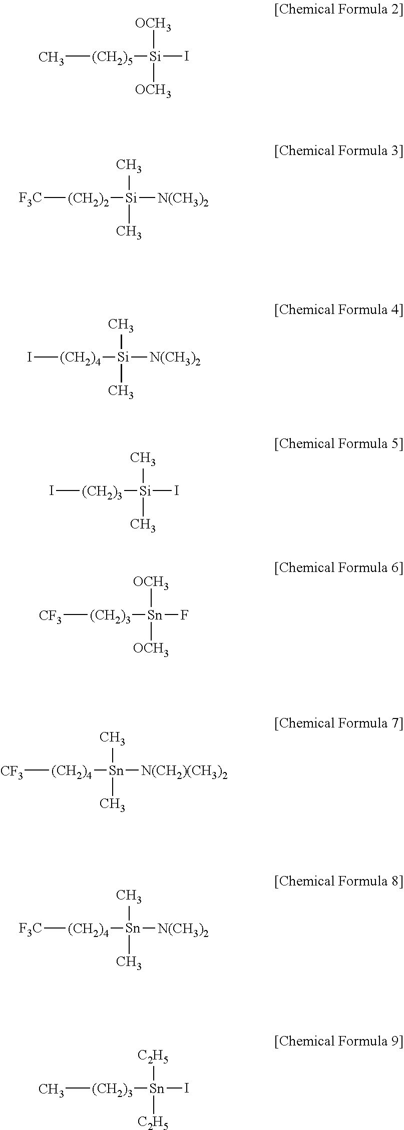

The precursor material expressed as Chemical Formula 1 is a precursor compound capable of forming a thin film or a metal thin film on a semiconductor substrate, and has a hydrophobic group, such as alkyl or olefin, formed at one end thereof and an amine group or a halogen group formed as the other end thereof. A bonding force with the photoresist layer 130 may be formed at one end. A bonding force with the substrate 110 may be formed at the other end.

Specifically, a carbon straight chain, such as alkyl or olefin, is formed at one end of the precursor material expressed as Chemical Formula 1. Accordingly, a bonding force attributable to the improvement of the van der Waals force can be improved, and a bonding force attributable to the physical entanglement of the carbon straight chain and the photoresist layer 130 can be improved. The bonding force with the photoresist layer 130 can be improved because surface deposition coverage is improved through the forming of a self-assembling monolayer. Furthermore, as the function group of R¹ is introduced, the bonding force with the photoresist layer 130, that is, hydrophobicity, can be further improved because a dipole moment is improved.

In particular, when R¹ is CF₃, the bonding force with the photoresist layer 130 is further improved because hydrophobicity is further increased. Upon exposure for forming a pattern, EUV dosage for forming a pattern can be reduced because the absorbance of an EUV light source becomes excellent.

Furthermore, if a halogen material is included as a function group, EUV dosage can be reduced due to excellent absorption efficiency of the halogen material itself.

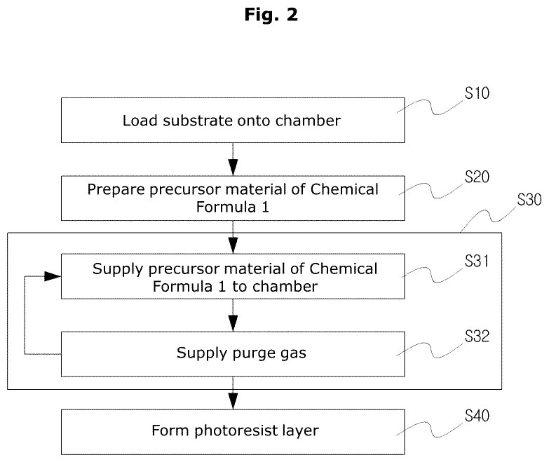

FIG. 2 is a process flowchart for describing a method of manufacturing the semiconductor device according to the present embodiment. The method of manufacturing a semiconductor device according to the present embodiment is described with reference to FIG. 2. Furthermore, the semiconductor device that is manufactured according to the present embodiment is illustrated in FIG. 1, for convenience of description.

First, FIG. 1 is a diagram schematically illustrating a stack structure of the semiconductor device 100 that is manufactured according to the method of manufacturing a semiconductor device according to the present embodiment.

The semiconductor device 100 that is manufactured according to the method of manufacturing a semiconductor device according to the present embodiment includes the substrate 110, the lower layer 120 formed on the substrate 110 by depositing the precursor of Chemical Formula 1, and the photoresist layer 130 formed on the lower layer 120.

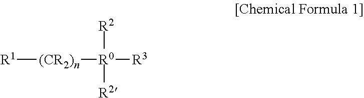

(In Chemical Formula 1, R0 is Si, Sn, Ge, Sb, In, Hf, Zr, Ti, or Te, R¹ is CH₃, CF₃, CH═CH₂, halogen, or phenyl, R² and R²′ are each independently an alkyl group or an alkoxy group, R³ is amine or halogen, R is hydrogen or halogen, and n is an integer of 1 to 7)

The precursor including Chemical Formula 1 is the same as that described above, and thus a redundant description thereof is omitted.

An element, a circuit, a film, etc. may be formed in the substrate 110. The substrate includes a base substrate 111 and a surface layer film 112. The base substrate 111 may be formed of a group IV material, such as silicon and germanium, or may be formed of a compound, such as a group III-V material, such as GsAs, GaN, InP, and InGaN, a group II-VI material, such as ZnSe, and a group IV-IV material, such as SiC and SiGe.

A surface of the substrate 110 may include silicon oxynitride (SiON) or amorphous carbon. Specifically, the surface layer film 112 including silicon oxynitride or amorphous carbon may be formed on a surface of the substrate. For example, the surface of the substrate 110 may include a silicon oxynitride film or an amorphous carbon film as the surface layer film 112.

As described above, the substrate 110 may include silicon oxynitride or amorphous carbon on the surface thereof. The surface of the substrate has a silicon oxynitride film. Accordingly, if the precursor expressed as Chemical Formula 1 includes an amine group, a high bonding force with the substrate 110 can be formed. Accordingly, a film can be easily formed by depositing the precursor expressed as Chemical Formula 1 on the substrate 110.

The lower layer 120 may be formed through an ALD process or a half ALD process.

The lower layer 120 may be formed by depositing the precursor expressed as Chemical Formula 1 on the substrate 110 through the ALD process. The thickness of the lower layer 120 may be 10 Å or less or may be 1 to 10 Å.

A conventional lower layer 120 is formed by a spin coating method and thickly formed 50 Å or more. In that case, minimum light dosage that is required to form a pattern of a semiconductor is much and an etching time is long. Accordingly, there is a problem in that a pattern collapse problem occurs because the photoresist layer 130 is also etched although only the lower layer 120 needs to be selectively etched for a pattern forming process.

In the semiconductor device 100 according to the present embodiment, the lower layer 120 having a thickness of 10 Å or less can be formed because the lower layer 120 is formed by using the ALD method. In this case, if the lower layer 120 is implemented in the form of an ultra thin film, a pattern can be formed without damaging the photoresist layer 130 because light dosage for forming a pattern can be reduced and an etching time can be reduced. Furthermore, a cost consumed for a process can be reduced because the amount of an etchant that is used upon etching can be reduced.

The ALD method may include a process of first vaporizing the precursor in a liquid state, which is expressed as Chemical Formula 1, depositing the precursor on the substrate 110, and purging the precursor. The process may be repeatedly performed by using the deposition and purge as one cycle.

In this case, when the vaporized precursor of Chemical Formula 1 is transported, an insert gas, such as argon (Ar), nitrogen (N₂), or helium (He), may also be used as carrier gas, for example, but the type of carrier gas is not limited thereto. Furthermore, the insert gas may be used as a purge gas that is used in the purge process, but the present disclosure is not limited thereto.

The photoresist layer 130 formed on the lower layer 120 may include at least one of a chemical amplified resist (CAR) type and a metal oxide resist (MOR) type.

FIG. 2 is a process flowchart for describing a method of manufacturing the semiconductor device 100 according to the present embodiment. The method of manufacturing the semiconductor device 100 according to the present embodiment is described with reference to FIG. 2.

The present embodiment includes a method of manufacturing the semiconductor device 100, including a process S10 of preparing the substrate 110, a process S20 of preparing the precursor of Chemical Formula 1, that is, a material for forming the lower layer 120, a process S30 of forming the lower layer 120 by depositing the precursor of Chemical Formula 1 on the substrate 110 by an atomic layer deposition (ALD) method, and a process S40 of forming the photoresist layer 130 on the lower layer 120.

The precursor expressed as Chemical Formula 1 is the same as that described above, and thus a redundant description thereof is omitted.

The process S10 is a process of preparing the substrate 110, and may be a process of inputting the substrate 110 to a reaction chamber.

An element, a circuit, a film, etc. is formed on the substrate 110. The substrate includes the base substrate 111 and the surface layer film 112. The base substrate 111 may be formed of the group IV material, such as silicon and germanium, or may be formed of a compound, such as the group III-V material, such as GsAs, GaN, InP, and InGaN, the group II-VI material, such as ZnSe, and the group IV-IV material, such as SiC and SiGe.

A surface of the substrate 110 may include silicon oxynitride or amorphous carbon. Specifically, the surface layer film 112 including silicon oxynitride or amorphous carbon may be formed on the surface of the substrate. For example, the surface of the substrate 110 may include a silicon oxynitride film or an amorphous carbon film as the surface layer film 112.

The process S20 is a process of preparing the precursor including Chemical Formula 1, that is, a material for forming the lower layer 120. The precursor including Chemical Formula 1 is present in the liquid state at room temperature. In this process, in order to apply the precursor to the ALD method, the precursor may be vaporized through a vaporizer.

The process S30 is a process of forming the lower layer 120 by supplying the precursor including Chemical Formula 1 to a chamber and making the precursor react therein. The process may be performed by repeatedly performing at least one cycle. Said one cycle is comprising both a process S31 of supplying the precursor including Chemical Formula 1 and a process of S32 of supplying a purge gas. This process may be performed in a temperature range of 100 to 250° C. Precursors that are defined depending on R⁰ to R³ have different decomposition temperatures depending on the type of precursor. Accordingly, it is preferred that the process is performed at a temperature less than a decomposition temperature of a corresponding precursor.

In the process S31, the vaporized precursor including Chemical Formula 1 is supplied to a chamber in which the substrate 110 is accommodated. In this case, the insert gas, such as argon (Ar), nitrogen (N₂), or helium (He), may be supplied to the chamber as a carrier gas along with the vaporized precursor including Chemical Formula 1.

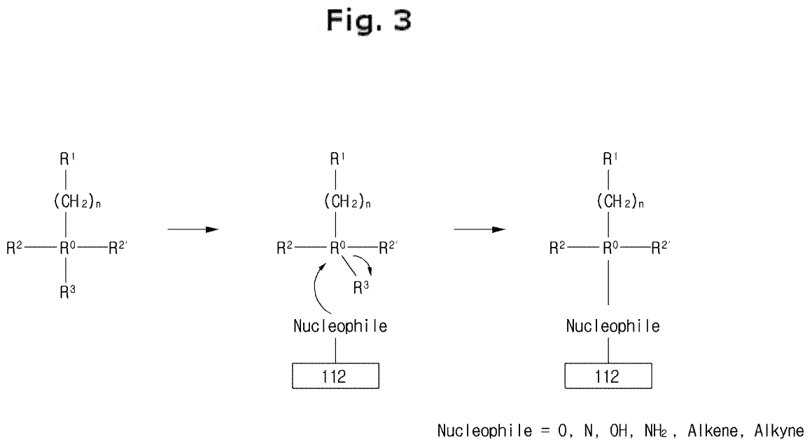

An amine group that is formed at one end of the precursor supplied to the chamber in which the substrate 110 is accommodated has hydrophilic properties, and may be deposited on a thin film on a surface of the substrate 110 by being combined with silicon oxynitride or amorphous carbon having hydrophilic properties on a surface of the substrate 110. Specifically, the amine group of the precursor including Chemical Formula 1 nay form a reaction part that is formed as the amine group is stripped at a high temperature and a monolayer in which the amine groups are arranged in a row by being bonded and combined with a hydroxyl group, an amino group, or sp2 carbon, that is, nucleophile on the surface of the substrate 110. Such series of processes may be more clearly understood with reference to FIG. 3.

FIG. 3 is a diagram simply illustrating a process of depositing a precursor according to an embodiment. In the embodiment illustrated in FIG. 3, R of the precursor represented as Chemical Formula 1 is exemplarily described through a precursor, that is, H.

First, when the precursor of Chemical Formula 1 is exposed to heat, R⁰ of the precursor is bonded with an unsaturated bonding, a hydroxyl group or an amino group, that is, nucleophile of the surface layer film 112 on a surface of the substrate 110. And R₃ falls off. Accordingly, the precursors including Chemical Formula 1 on a surface of the surface layer film 112 may be combined in a row to form the monolayer.

Meanwhile, the process S32 is performed in order to purge reactants that have not reacted in a previous process and byproducts including gas products generated through reactions, and may be performed by supplying an insert gas to the chamber. In this case, argon (Ar), nitrogen (N₂), or helium (He), for example, may be used as the insert gas, but the present disclosure is not limited thereto.

The process S40 is a process of forming the photoresist layer 130 on the lower layer 120, and may be a process of forming the photoresist layer 130 on the lower layer 120 by using the ALD method. In this case, the photoresist layer 130 may be formed of any one material of a chemical amplified resist (CAR) type and a metal oxide resist (MOR) type, or may include the CAR type and the MOR type.

As described above, the lower layer 120 is formed in the form of the monolayer in which the precursors including Chemical Formula 1 are arranged in a row. In this case, the hydrophilic part is disposed on the side of the substrate 110, and the hydrophobic part of an alkyl or olefin carbon chain structure is disposed on the other side thereof. When the lower layer 120 is deposited on the substrate 110 through the process of forming the lower layer 120, a surface of the lower layer 120, which is exposed to the outside, has hydrophobic properties. Accordingly, when the photoresist layer 130 is formed on a surface of the lower layer 120 that is hydrophobic by using a photoresist material, a strong bonding force is formed because the van der Waals force acts between the surface of the lower layer 120 that is hydrophobic and the photoresist layer 130 that is hydrophobic. A carbon chain structure of the precursor including Chemical Formula 1 may form an additional bonding force by being entangled with the photoresist layer 130. In particular, when R¹ of the precursor of Chemical Formula 1 is CF₃ or a phenyl group, a bonding force with the photoresist layer is further improved. A bonding force when R¹ of the precursor of Chemical Formula 1 is CF₃, is the most excellent.

The semiconductor device 100 according to the present embodiment can reduce EUV dosage for forming a pattern because the EUV absorption factor of the lower layer 120 is improved. The lower layer 120 is formed of a thin film of 10 Å or less through an ALD process. Accordingly, damage to (the pattern collapse of) the photoresist layer 130 can be prevented because the EUV exposure time of the photoresist layer 130 and the time taken for the photoresist layer to be exposed to an etchant can be reduced. A reduction of process costs and a reduction of a process time can be achieved through a reduction of dosage, a reduction of the amount of an etchant used, a reduction of the time taken to form a pattern, etc.

Furthermore, the semiconductor device 100 according to the present embodiment has a similar minimum critical dimension (CD) value in which a line width reduction (LWR) and a pattern are damaged compared to the semiconductor device 100 of a comparison example in which the lower layer 120 is formed by a common spin coating process, but could significantly reduce dosage (dose to size, DtS). It could be seen that the DtS was reduced in a range of about 3 to 30% compared to a common spin-coating method.

Although the embodiments of the present disclosure have been described above, a person who has ordinary knowledge in the art may variously modify and change the present disclosure by supplementing, changing, deleting, or adding a component without departing from the spirit of the present disclosure written in the claims. All of such embodiments may be said to belong to the scope of rights of the present disclosure.

### INDUSTRIAL APPLICABILITY

The method of manufacturing the semiconductor device using the precursor compound for forming a thin film according to the present disclosure has an industrial applicability because it has an effect in that it can reduce an exposure time for forming a pattern and prevent the pattern collapse of the photoresist layer by minimizing or omitting the thickness of the lower layer having etch selectivity similar to that of the photoresist upon etching after exposure.

1. A precursor compound for forming a thin film, the precursor compound comprising a material of Chemical Formula 1: 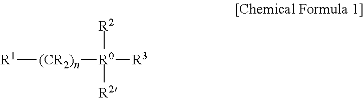
wherein in the Chemical Formula 1, R⁰ is Si, Sn, Ge, Sb, In, Hf, Zr, Ti, or Te, R¹ is CH₃, CF₃, CH═CH₂, halogen, or phenyl, R² and R²′ are each independently an alkyl group or an alkoxy group, R³ is amine or halogen, R is hydrogen or halogen, and n is an integer of 1 to 7.

2. The precursor compound of claim 1, wherein in the Chemical Formula 1, R⁰ is Si or Sn, R¹ is CF₃ or I, R² and R²′ are each independently CH₃, C₂H₅, C₃H₇, OCH₃, or OC₂H₅, R³ is N(CH₃)₂ or N[(CH₂)CH₃]₂, and R is H.

3. The precursor compound of claim 2, wherein n in the Chemical Formula 1 is an integer of 1 to 4.

4. The precursor compound of claim 1, wherein the precursor compound for forming the thin film is any one of materials expressed as Chemical Formula 2 to Chemical Formula 9 below:

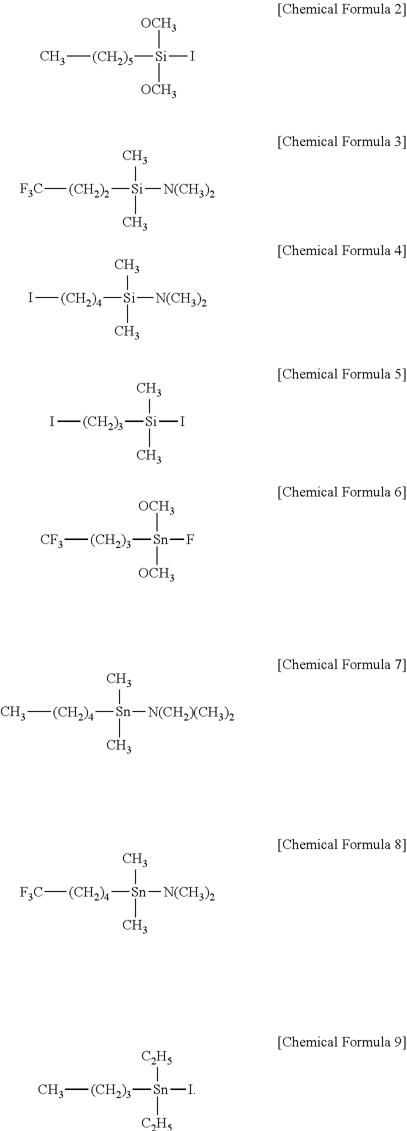

5. The precursor compound of claim 1, wherein the precursor compound for forming the thin film is a precursor that forms the thin film on a surface of a semiconductor substrate.

6. The precursor compound of claim 5, wherein a thickness of the thin film is 10 Å or less.

7. The precursor compound of claim 5, wherein the surface of the semiconductor substrate comprises silicon oxynitride or amorphous carbon.

8. A method of manufacturing a semiconductor device, comprising:
preparing a substrate;
forming a lower layer by depositing a precursor of Chemical Formula 1 on the substrate by an atomic layer deposition (ALD) method; and
forming a photoresist layer on the lower layer: 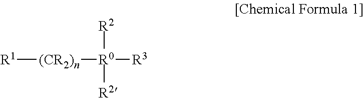
wherein in the Chemical Formula 1, R⁰ is Si, Sn, Ge, Sb, In, Hf, Zr, Ti, or Te, R¹ is CH₃, CF₃, CH═CH₂, halogen, or phenyl, R² and R²′ are each independently an alkyl group or an alkoxy group, R³ is amine or halogen, R is hydrogen or halogen, and n is an integer of 1 to 7.

9. The method of claim 8, wherein:
the forming of the lower layer comprises supplying the precursor comprising the Chemical Formula 1 and supplying a purge gas, and
a cycle in which the supplying of the precursor and the supplying of the purge gas are defined as one cycle is repeated at least once.

10. The method of claim 8, wherein the forming of the lower layer is performed at a temperature of 100 to 250° C.

11. The method of claim 8, wherein a surface of the substrate comprises silicon oxynitride or amorphous carbon.

12. The method of claim 8, wherein a thickness of the lower layer is 10 Å or less.

13. The method of claim 8, wherein the precursor is any one of materials expressed as Chemical Formula 2 to Chemical Formula 9 below: [chemical structure]
